(19) United States
(12) Patent Application Publication
(10) Pub. No.: US 2009/0085051 A1
(43) Pub. Date: Apr. 2, 2009

(54) Light emitting diode device

(76) Inventors: Chung-Chuan Hsieh, Panchiao City (TW); Chien-Chang Pei, Linkou Township (TW); Chia-Hsien Chang, Yongjing Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/078,490

(22) Filed: Apr. 1, 2008

(30) Foreign Application Priority Data
Oct. 1, 2007 (TW) 96216404

(51) Int. Cl. H01L 33/00

(52) U.S. Cl. 257/98; 257/E33.058; 257/E33.061

(57) ABSTRACT

A light emitting diode device includes a light emitting diode chip, a thermal conducting part, two electric conducting parts and two first conducting wires. The light emitting diode chip has a surface and two electrodes disposed on the surface. The thermal conducting part is electrically insulated to the electrodes. The thermal conducting part includes a core bearing the light emitting diode chip, and four outward lead-frames connected to the core. The electric conducting parts are electrically insulated to the thermal conducting part. The first conducting wires have ends electrically connected to the electrodes.

### RELATED APPLICATIONS

This application claims priority to Taiwan Application Serial Number 96216404, filed Oct. 1, 2007, which is herein incorporated by reference.

### BACKGROUND

1. Field of Invention The present invention relates to a light emitting diode device. More particularly, the present invention relates to a surface mounted light emitting diode device.

2. Description of Related Art

For the convenience of carrying electronic devices, the electronic devices need to be light and small. Therefore the display in an electronic device needs to be small as well, such as a mobile phone display. The conventional light emitting diode device usually includes a light emitting diode chip and chip carrier. The chip carrier carries the light emitting diode chip, conducts the thermal energy to the environment, and also conducts the electric current to the electrode of the light emitting diode chip.

However, because the chip carrier conducts both the thermal energy and the electric current, it makes the temperature of the chip carrier increase. Therefore, as a result the resistance of the chip carrier increases and the conductivity decreases.

Therefore, there is a need for a new light emitting diode device which can conduct the electric current and the thermal energy efficiently.

### SUMMARY

According to one embodiment of the present invention, a light emitting diode device includes a light emitting diode chip, a thermal conducting part, two electric conducting parts and two first conducting wires. The light emitting diode chip has a surface and two electrodes disposed on the surface. The thermal conducting part is electrically insulated to the electrodes. The thermal conducting part includes a core bearing the light emitting diode chip, and four outward lead-frames connected to the core. The electric conducting parts are electrically insulated to the thermal conducting part. The first conducting wires have ends electrically connected to the electrodes.

According to another embodiment of the present invention, a light emitting diode device includes a light emitting diode chip, a substrate, a conducting area, a thermal conducting part, a first electric conducting part, a second electric conducting part, a first conducting wire, and a second conducting wire.

The light emitting diode chip has a first electrode and a second electrode disposed on different surfaces of the light emitting diode chip. The substrate is electrical insulating. The conducting area is electrically connected to the second electrode, and is disposed on a surface of the substrate, in which the surface faces the light emitting diode chip. The thermal conducting part has a core for supporting the substrate, and four outward lead-frames connected to the core.

The first electric conducting part and the second electric conducting part are electrically insulating to the thermal conducting part. The first conducting wire is electrically connected to the first electrode and the first electric conducting part. The second conducting wire is electrically connected to the second electric conducting part and the conducting area on the surface of the substrate.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 shows a light emitting diode device according to one embodiment of the present invention;

FIG. 2 shows a light emitting diode device with the cover according to one embodiment of the present invention;

FIG. 3 shows a light emitting diode device according to another embodiment of the present invention.

FIG. 4 shows a light emitting diode device with the cover according to another embodiment of the present invention;

FIG. 5 shows a light emitting diode device according to the other embodiment of the present invention; and

FIG. 6 shows a light emitting diode device with the cover according to the other embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

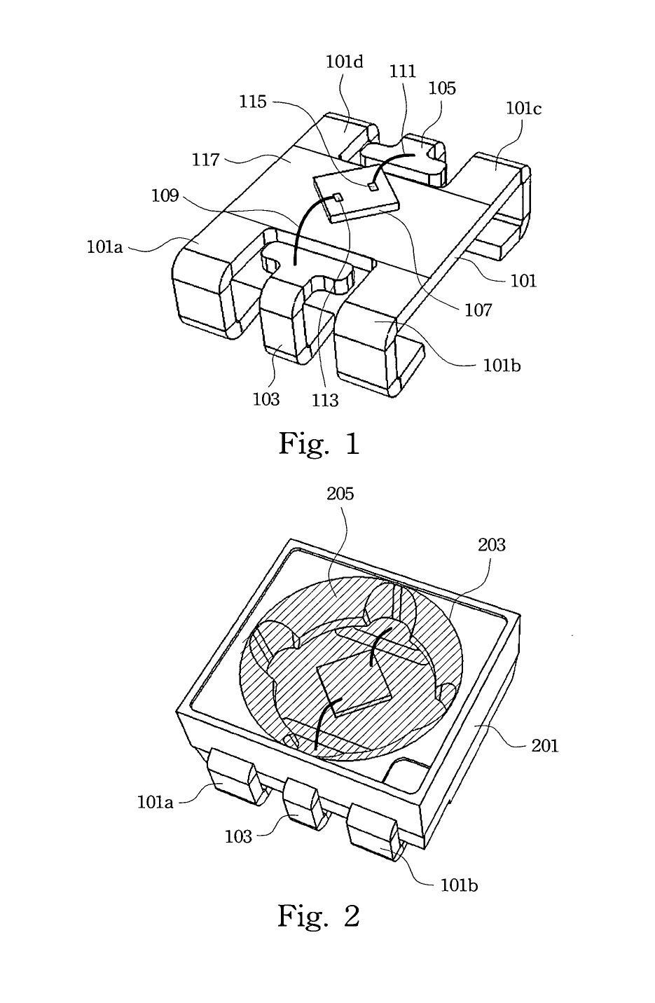

FIG. 1 shows a light emitting diode device according to one embodiment of the present invention. The light emitting diode device includes a light emitting diode chip 107, a thermal conducting part 101, the electric conducting part 103\105, and the first conducting wire 109\111. The light emitting diode chip 107 has the electrode 113 and the electrode 115 disposed on the same surface of the light emitting diode chip 107. One end of the first conducting wire 109 and the first conducting wire 111 are electrically connected to the electrodes 113 and electrode 115 respectively. The other ends of the first conducting wire 109 and the first conducting wire 111 are electrically connected to the electric conducting part 103 and electric conducting part 105 respectively.

The thermal conducting part 101, made of metal, is electrically insulated to the electrode 113\115. The thermal conducting part 101 includes a core 117 bearing the light emitting diode chip 107, and outward lead-frame 101a\101b\101c\101d connected to the core 117. The electric conducting part 103\105 is electrically insulated to the thermal conducting part 117. The outward lead-frame 101a\101b\101c\101d and the electric conducting part 103\105 have U shapes as shown, and can be surface mounted on a board.

In the light emitting diode device of this embodiment, the current is conducted to the electrode 113\115 through the electric conducting part 103\105, while the thermal energy generated by the light emitting diode chip 107 can be conducted to the environment (such as a board) through the outward lead-frame 101a\101b\101c\101d. Because the current and the thermal energy are conducted through the electric conducting part 103\105 and the outward lead-frame 101a\101b\101c\101d respectively, the temperature of the electric conducting part 103\105 is not increased because of the thermal energy. Therefore, the resistance of the electric conducting part 103\105 is not increased, and the electric conducting part 103\105 can conduct the current effectively.

FIG. 2 shows a light emitting diode device with the cover according to one embodiment of the present invention. In this embodiment, the cover 201, having the first hole 203, covers the light emitting diode device. The outward lead-frame 101a\101b\101c\101d and the electric conducting part 103\105 extends through the second holes on the side of the cover 201 from the core 117.

The cover 201 reflects, mixes and gathers the light generated by the light emitting diode chip 107, and transmits the light to the environment through the hole 203. The first hole 203 is filled with transparent colloid 205 for protecting the light emitting diode chip 107 inside. The transparent colloid 205 can be made of epoxy resin, acrylic or silica gel. In addition, the transparent colloid 205 can be colored by adding phosphor powders.

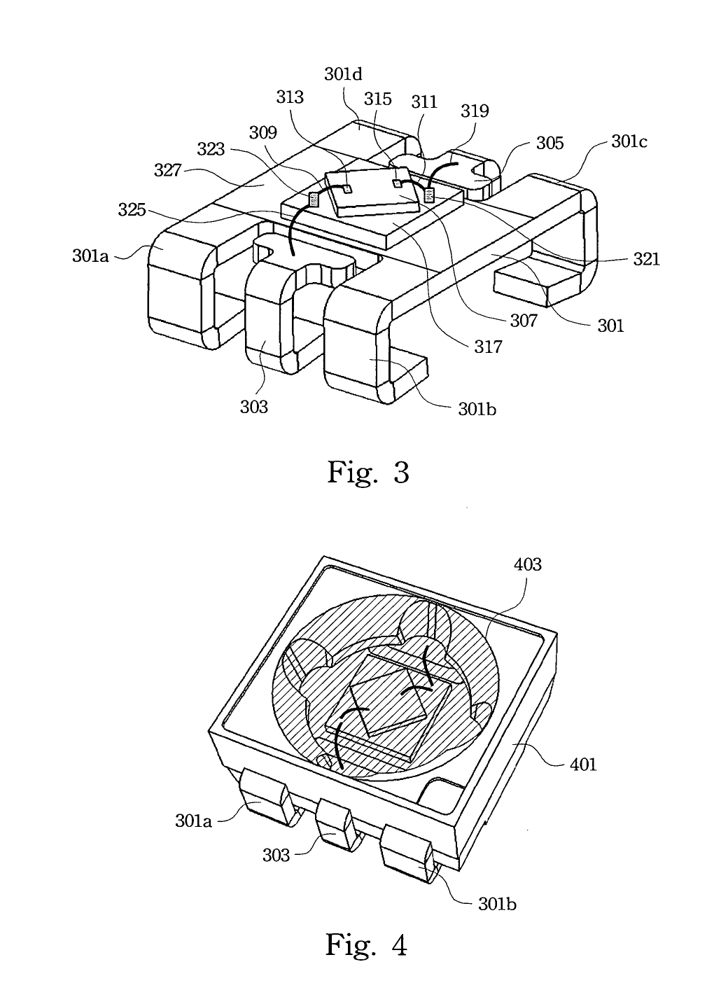

FIG. 3 shows a light emitting diode device according to another embodiment of the present invention. The light emitting diode device includes a light emitting diode chip 307, a thermal conducting part 301, the electric conducting part 303\305, and the first conducting wire 309\311, second conducting wire 319\325, and substrate 317. The light emitting diode chip 307 has the electrode 313 and the electrode 315 disposed on the same surface of the light emitting diode chip 307.

Comparing with the light emitting diode device shown in FIG. 1, the light emitting diode device in this embodiment further includes the insulating substrate 317 disposed between the core 327 and the light emitting diode chip 307. The conducting area 321 and the conducting area 323 which are insulated to each other are disposed on a surface facing the light emitting diode chip of the substrate 317.

One end of the first conducting wire 309\311 is electrically connected to the electrode 313\315, while the other end of the first conducting wire 309\311 is electrically connected to the conducting area 323\321 disposed on the substrate. The conducting area 323\321 is electrically connected to the electric conducting part 303\305 through the second conducting wire 319\325.

The substrate 317 with expansion coefficient (swell factor) near the light emitting diode chip (such as material with expansion coefficient between the expansion coefficient of the metal and the expansion coefficient of the light emitting diode chip) is selected for buffering the thermal energy. The stress problem can be prevented because the thermal expansion difference between the light emitting diode 307 and the thermal conducting part 301 is small.

FIG. 4 shows the light emitting diode device according to another embodiment of the present invention. A cover 401 with first hole 403 is used for covering the light emitting diode device. The structure of cover 401 is similar to the structure of cover 201 shown in FIG. 2.

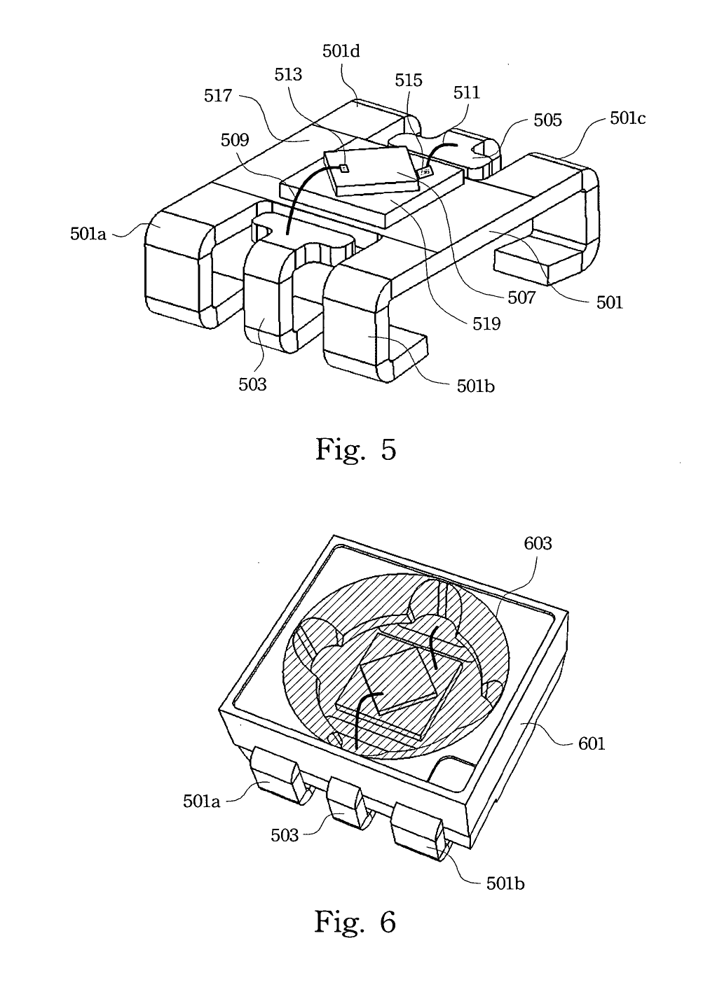

FIG. 5 shows the light emitting diode device according to another embodiment of the present invention. The light emitting diode device includes the light emitting diode chip 507, the thermal conducting part 503\505, the first conducting wire 509, the second conducting wire 511 and a substrate 519. The thermal conducting part 501 includes a core 517 for supporting the light emitting diode chip 507 and the outward lead-frame 501a\501b\501c\501d connected to the core 517.

Comparing with the embodiment shown above, the electrode 513 is disposed above the light emitting diode 507, and the other electrode is disposed between the light emitting diode chip 507 and the substrate 519. The conducting area 515 disposed on the substrate 519 is electrically connected to the electrode disposed between the light emitting diode chip 507 and the substrate 519. The second conducting wire 511 is electrically connected to the electric conducting part 505 and the conducting area 515 on the substrate 519.

FIG. 6 shows the light emitting diode device with the cover according to another embodiment of the present invention. Comparing to the light emitting diode device shown in FIG. 5, the cover 601 with first hole 603 is used for covering the light emitting diode device. The structure of cover 601 is similar to the structure of cover 201 shown in FIG. 2.

According to the above embodiments, the thermal energy is dissipated more efficiently with the additional outward lead-frames. In addition, by separating the electric conducting parts from the outward lead-frames, the electric conducting parts merely need to conduct current, which present the resistance from increasing, and the electric conductivity is promoted as a result.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light emitting diode device, comprising:
a light emitting diode chip having two electrodes disposed on a surface of the light emitting diode chip;
a thermal conducting part electrically insulated to the electrodes, wherein the thermal conducting part comprises:
a core bearing the light emitting diode chip; and
four outward lead-frames connected to the core;
two electric conducting parts electrically insulated to the thermal conducting part; and
two first conducting wires having ends electrically connected to the electrodes.

2. The light emitting diode device of claim 1, further comprising a cover, wherein the cover comprises:
a first hole for transmitting the light of the light emitting diode chip; and
a cover side having a plurality of second holes, wherein the outward lead-frames and the electric conducting parts extends through the second holes from the core.

3. The light emitting diode device of claim 2, further comprising a transparent colloid filled in the first hole.

4. The light emitting diode device of claim 3, wherein the transparent colloid is epoxy resin, acrylic or silica gel.

5. The light emitting diode device of claim 3, further comprising phosphor powders disposed in the transparent colloid.

6. The light emitting diode device of claim 1, wherein the outward lead-frames and the electric conducting parts are surface mounted on a board.

7. The light emitting diode device of claim 6, wherein the surface mounted outward lead-frames and the surface mounted electric conducting parts have U shapes.

8. The light emitting diode device of claim 1, wherein the thermal conducting part is made of metal.

9. The light emitting diode device of claim 1, wherein the other ends of the first conducting wires are electrically connected to the electric conducting parts.

10. The light emitting diode device of claim 1, further comprising a substrate and two conducting areas which are insulated to each other, wherein the substrate is insulated and disposed between the core and the light emitting diode chip, and the conducting areas are disposed on a surface of the substrate facing the light emitting diode chip.

11. The light emitting diode device of claim 10, wherein the other ends of the first conducting wires are electrically connected to the conducting areas disposed on the substrate.

12. The light emitting diode device of claim 11, further comprising two second conducting wires electrically connected to the conducting areas on the substrate and the electric conducting parts.

13. A light emitting diode device, comprising:
a light emitting diode chip having a first electrodes and a second electrode disposed on different surfaces of the light emitting diode chip;
a substrate, wherein the substrate is electrical insulating;
a conducting area electrically connected to the second electrode and disposed on a surface of the substrate, wherein the surface faces the light emitting diode chip;
a thermal conducting part, comprising:
a core for supporting the substrate; and
four outward lead-frames connected to the core;
a first electric conducting part and a second electric conducting part electrically insulating to the thermal conducting part;
a first conducting wire electrically connected to the first electrode and the first electric conducting part; and
a second conducting wire electrically connected to the second electric conducting part and the conducting area on the surface of the substrate.

14. The light emitting diode device of claim 13, further comprising a cover, wherein the cover comprises:
a first hole for transmitting the light of the light emitting diode chip; and
a cover side having a plurality of second holes, wherein the outward lead-frames and the electric conducting parts extends through the second holes from the core.

15. The light emitting diode device of claim 14, further comprising a transparent colloid filled in the first hole.

16. The light emitting diode device of claim 15, wherein the transparent colloid is epoxy resin, acrylic or silica gel.

17. The light emitting diode device of claim 15, further comprising phosphor powders disposed in the transparent colloid.

18. The light emitting diode device of claim 13, wherein the outward lead-frames and the electric conducting parts are surface mounted on a board.

19. The light emitting diode device of claim 18, wherein the surface mounted outward lead-frames and the surface mounted electric conducting parts have U shapes.

20. The light emitting diode device of claim 13, wherein the thermal conducting part is made of metal.
